(19) United States
(12) Patent Application Publication
(10) Pub. No.: US 2024/0233817 A1
(43) Pub. Date: Jul. 11, 2024

(54) LIFETIME MIXED LEVEL NON-VOLATILE MEMORY SYSTEM

(71) Applicant: Vervain, LLC, Dallas, TX (US)

(72) Inventor: G.R. Mohan Rao, Allen, TX (US)

(21) Appl. No.: 18/613,466

(22) Filed: Mar. 22, 2024

Related U.S. Application Data
(63) Continuation of application No. 18/390,193, filed on Dec. 20, 2023, now Pat. No. 11,967,370.
Application No. 18/390,193 is a continuation of application No. 18/387,546, filed on Nov. 7, 2023, now Pat. No. 11,967,369.
Application No. 18/387,546 is a continuation of application No. 17/203,385, filed on Mar. 16, 2021, now Pat. No. 11,830,546.
Application No. 17/203,385 is a continuation of application No. 16/006,299, filed on Jun. 12, 2018, now Pat. No. 10,950,300.
Application No. 16/006,299 is a continuation of application No. 14/950,553, filed on Nov. 24, 2015, now Pat. No. 9,997,240.
Application No. 14/950,553 is a continuation of application No. 14/525,411, filed on Oct. 28, 2014, now Pat. No. 9,196,385.
Application No. 14/525,411 is a division of application No. 13/455,267, filed on Apr. 25, 2012, now Pat. No. 8,891,298.
(60) Provisional application No. 61/509,257, filed on Jul. 19, 2011.

(51) Int. Cl. G11C 11/56; G06F 11/10; G06F 12/02; G11C 16/16; G11C 16/34; G11C 29/00; G11C 29/52

(52) U.S. Cl. CPC G11C 11/5635; G06F 11/1068; G06F 11/1072; G06F 12/0246; G11C 11/5621; G11C 11/5678; G11C 16/16; G11C 16/3495; G11C 29/52; G11C 29/76; G06F 2212/7202; G11C 2211/5641

(57) ABSTRACT

A controller for managing at least one MLC non-volatile memory space including at least one MLC non-volatile memory element and at least one SLC non-volatile memory space including at least one SLC non-volatile memory element. The controller is adapted to determine if a range of addresses listed by an entry and mapped to the at least one MLC non-volatile memory element fails a data integrity test performed at the controller based upon received data retained at the controller and which received data is stored in the at least one MLC memory element as stored data. In the event of such a failure, the controller remaps said entry to an the at least one SLC non-volatile memory element.

### CROSS-REFERENCE TO RELATED APPLICATIONS

This application is a continuation of U.S. application Ser. No. 18/390,193, filed Dec. 20, 2023, entitled LIFETIME MIXED LEVEL NON-VOLATILE MEMORY SYSTEM (Atty. Dkt. No. VRVN60-35863), which is a continuation of U.S. application Ser. No. 18/387,546, filed Nov. 7, 2023, entitled LIFETIME MIXED LEVEL NON-VOLATILE MEMORY SYSTEM (Atty. Dkt. No. VRVN60-35840), which is a continuation of U.S. application Ser. No. 17/203,385, filed Mar. 16, 2021, entitled LIFETIME MIXED LEVEL NON-VOLATILE MEMORY SYSTEM, issued as U.S. Pat. No. 11,830,546 on Nov. 28, 2023 (Atty. Dkt. No. VRVN60-35360), which is a continuation of U.S. patent application Ser. No. 16/006,299, filed Jun. 12, 2018, entitled LIFETIME MIXED LEVEL NON-VOLATILE MEMORY SYSTEM, issued as U.S. Pat. No. 10,950,300 on Mar. 16, 2021 (Atty. Dkt. No. VRVN60-34138), which is a continuation of U.S. patent application Ser. No. 14/950,553, filed Nov. 24, 2015, entitled LIFETIME MIXED LEVEL NON-VOLATILE MEMORY SYSTEM, issued as U.S. Pat. No. 9,997,240 on Jun. 12, 2018 (Atty. Dkt. No. VRVN60-32800), which a continuation of U.S. patent application Ser. No. 14/525,411, filed Oct. 28, 2014, entitled LIFETIME MIXED LEVEL NON-VOLATILE MEMORY SYSTEM, issued as U.S. Pat. No. 9,196,385 on Nov. 24, 2015 (Atty. Dkt. No. VRVN60-32620), which is a divisional of U.S. patent application Ser. No. 13/455,267, filed Apr. 25, 2012, LIFETIME MIXED LEVEL NON-VOLATILE MEMORY SYSTEM, issued as U.S. Pat. No. 8,891,298 on Nov. 18, 2014 (Atty. Dkt. No. VRVN60-32619), which claims the benefit of U.S. Provisional Application No. 61/509,257, filed Jul. 19, 2011, entitled LIFETIME MIXED LEVEL NAND FLASH SYSTEM. All the foregoing including application Ser No. 18/390,193, Ser. No. 18/387,546, Ser. No. 17/203,385, Ser. No. 16/006,299, Ser. No. 14/950,553, Ser. No. 14/525,411, Ser. No. 13/455,267, 61/509,257 and U.S. Pat. Nos. 11,830,546, 10,950,300, 9,997,240, 9,196,385 and 8,891,298 are incorporated by reference herein in their entirety.

application Ser. No. 17/203,385 is also related to U.S. patent application Ser. No. 12/256,362, filed Oct. 22, 2008, entitled NONSVOLATILE MEMORY SYSTEMS WITH EMBEDDED FAST READ AND WRITE MEMORIES, and U.S. patent application Ser. No. 12/915,177, filed Oct. 29, 2010, entitled NONVOLATILE MEMORY SYSTEMS WITH EMBEDDED FAST READ AND WRITE MEMORIES, the disclosures of which are hereby incorporated by reference in their entirety.

### TECHNICAL FIELD

This application relates to a system and method for providing reliable storage through the use of non-volatile memories and, more particularly, to a system and method of increasing the reliability and lifetime of a NAND flash storage system, module, or chip through the use of a combination of single-level cell (SLC) and multi-level cell (MLC) NAND flash storage without substantially raising the cost of the NAND flash storage system. The memory in a total non-volatile memory system may contain some SRAM (static random-access memory), DRAM (dynamic RAM), RRAM (resistive RAM), PCM (phase change memory), MAGRAM (magnetic random-access memory), NAND flash, and one or more HDDs (hard disk drives) when storage of the order of several terabytes is required. The SLC non-volatile memory can be flash, PCM, RRAM, MAGRAM or any other solid-state non-volatile memory as long as it has endurance that is superior to that of MLC flash, and it provides for data access speeds that are faster than that of MLC flash or rotating storage media (e.g., HDDs).

### BACKGROUND

Non-volatile memories provide long-term storage of data. More particularly, non-volatile memories can retain the stored data even when not powered. Magnetic (rotating) hard disk drives (HDD) dominate this storage medium due to lower cost compared to solid state disks (SSD). Optical (rotating) disks, tape drives and others have a smaller role in long-term storage systems. SSDs are preferred for their superior performance (fast access time), mechanical reliability and ruggedness, and portability. Flash memory, more specifically NAND flash, is the dominant SSD medium today.

RRAM, PCM, MAGRAM and others, will likely play a larger role in the future, each of them having their own advantages and disadvantages. They may ultimately replace flash memories, initially for use as a “write buffer” and later to replace “SLC flash” and “MLC flash.” MLC NAND flash is a flash memory technology using multiple levels per cell to allow more bits to be stored using the same number of transistors. In SLC NAND flash technology, each cell can exist in one of two states, storing one bit of information per cell. Most MLC NAND flash memory has four possible states per cell, so it can store two bits of information per cell.

These semiconductor technology driven “flash alternatives,” i.e., RRAM, PCM, MAGRAM and others, have several advantages over any (SLC or MLC) flash because they: 1) allow data to be written over existing data (without prior erase of existing data), 2) allow for an erase of individual bytes or pages (instead of having to erase an entire block), and 3) possess superior endurance (1,000,000 write-erase cycles compared to typical 100,000 cycles for SLC flash and less than 10,000 cycles for MLC flash).

HDDs have several platters. Each platter contains 250-5,000 tracks (concentric circles). Each track contains 64 to 256 sectors. Each sector contains 512 bytes of data and has a unique “physical (memory) address.” A plurality of sectors is typically combined to form a “logical block” having a unique “logical address.” This logical address is the address at which the logical block of physical sectors appears to reside from the perspective of an executing application program. The size of each logical block and its logical address (and/or address ranges/boundaries) is optimized for the particular operating system (OS) and software applications executed by the host processor. A computer OS organizes data as “files.” Each file may be located (stored) in either a single logical block or a plurality of logical blocks, and therefore, the location of files typically traverses the boundaries of individual (physical) sectors. Sometimes, a plurality of files has to be combined and/or modified, which poses an enormous challenge for the memory controller device of a non-volatile memory system.

SSDs are slowly encroaching on the HDD space and the vast majority of NAND flash in enterprise servers utilizes a SLC architecture, which further comprises a NAND flash controller and a flash translation layer (FTL). NAND flash devices are generally fragmented into a number of identically sized blocks, each of which is further segmented into some number of pages. It should be noted that asymmetrical block sizes, as well as page sizes, are also acceptable within a device or a module containing devices. For example, a block may comprise 32 to 64 pages, each of which incorporates 2-4 Kbit of memory. In addition, the process of writing data to a NAND flash memory device is complicated by the fact that, during normal operation of, for example, single-level storage (SLC), erased bits (usually all bits in a block with the value of ‘1’) can only be changed to the opposite state (usually ‘0’) once before the entire block must be erased. Blocks can only be erased in their entirety, and, when erased, are usually written to ‘1’ bits. However, if an erased block is already there, and if the addresses (block, page, etc.) are allowed, data can be written immediately; if not, a block has to be erased before it can be written to.

FTL is the driver that works in conjunction with an existing operating system (or, in some embedded applications, as the operating system) to make linear flash memory appear to the system like a disk drive, i.e., it emulates a HDD. This is achieved by creating “virtual” small blocks of data, or sectors, out of flash's large erase blocks and managing data on the flash so that it appears to be “write in place” when in fact it is being stored in different locations in the flash. FTL further manages the flash so that there are clean/erased places to store data.

Given the limited number of writes that individual blocks within flash devices can tolerate, wear leveling algorithms are used within the flash devices (as firmware commonly known as FTL or managed by a controller) to attempt to ensure that “hot” blocks, i.e., blocks that are frequently written, are not rendered unusable much faster than other blocks. This task is usually performed within a flash translation layer. In most cases, the controller maintains a lookup table to translate the memory array physical block address (PBA) to the logical block address (LBA) used by the host system. The controller's wear-leveling algorithm determines which physical block to use each time data is programmed, eliminating the relevance of the physical location of data and enabling data to be stored anywhere within the memory array and thus prolonging the service life of the flash memory. Depending on the wear-leveling method used, the controller typically either writes to the available erased block with the lowest erase count (dynamic wear leveling); or it selects an available target block with the lowest overall erase count, erases the block if necessary, writes new data to the block, and ensures that blocks of static data are moved when their block erase count is below a certain threshold (static wear leveling).

MLC NAND flash SSDs are slowly replacing and/or coexisting with SLC NAND flash in newer SSD systems. MLC allows a single cell to store multiple bits, and accordingly, to assume more than two values; i.e., ‘0’ or ‘1’. Most MLC NAND flash architectures allow up to four (4) values per cell; i.e., ‘00’, ‘01’, ‘10’, or ‘11’. Generally, MLC NAND flash enjoys greater density than SLC NAND flash, at the cost of a decrease in access speed and lifetime (endurance). It should be noted, however, that even SLC NAND flash has a considerably lower lifetime (endurance) than rotating magnetic media (e.g., HDDs), being able to withstand only between 50,000 and 100,000 writes, and MLC NAND flash has a much lower lifetime (endurance) than SLC NAND flash, being able to withstand only between 3,000 and 10,000 writes. As is well known in the art, any “write” or “program” to a block in NAND flash (floating gate) requires an “erase” (of a block) before “write.”

Despite its limitations, there are a number of applications that lend themselves to the use of MLC flash. Generally, MLC flash is used in applications where data is read many times (but written few times) and physical size is an issue. For example, flash memory cards for use in digital cameras would be a good application of MLC flash, as MLC can provide higher density memory at lower cost than SLC memory.

When a non-volatile storage system combines HDD, SLC and MLC (setting aside volatile memory for buffering, caching etc) in a single (hybrid) system, new improvements and solutions are required to manage the methods of writing data optimally for improved life time (endurance) of flash memory. Accordingly, various embodiments of a NAND flash storage system that provides long lifetime (endurance) storage at low cost are described herein.

The following description is presented to enable one of ordinary skill in the art to make and use the disclosure and is provided in the context of a patent application and its requirements. Various modifications to the preferred embodiment and the generic principles and features described herein will be readily apparent to those skilled in the art. Thus, the present disclosure is not intended to be limited to the embodiments shown, but is to be accorded the widest scope consistent with the principles and features described herein.

### SUMMARY

The present invention, as disclosed and described herein, in one aspect thereof comprises a system for storing data. An MLC non-volatile memory space includes at least one MLC non-volatile memory element. An SLC non-volatile memory module space includes at least one SLC non-volatile memory element. A controller coupled to the at least one MLC non-volatile memory element and the at least one SLC non-volatile memory element is adapted to maintain an address map of the MLC and SLC non-volatile memory spaces. The address map comprises a list of logical address ranges accessible by a computer system. The computer system has at least one processor. The list of logical address ranges has a minimum quanta of addresses. Each entry in the list of logical address ranges maps to a similar range of physical addresses within either the at least one SLC non-volatile memory element or within the at least one MLC non-volatile memory element. The controller is further adapted to determine if a range of addresses listed by an entry and mapped to a similar range of physical addresses within the at least one MLC non-volatile memory element fails a data integrity test performed at the controller during a read operation, read stored data from the MLC non-volatile memory space containing at least one MLC non-volatile memory element, and, in an event of such a failure, the controller remaps the entry to a next available equivalent range of physical addresses within the at least one SLC non-volatile memory element.

### BRIEF DESCRIPTION OF THE DRAWINGS

The present disclosure will be more fully understood by reference to the following detailed description of one or more preferred embodiments when read in conjunction with the accompanying drawings, in which like reference characters refer to like parts throughout the views and in which:

FIG. 1 is a block diagram of a computer system incorporating one embodiment of the present disclosure;

FIGS. 2A and 2B are drawings depicting a translation table/address map in accordance with one embodiment of the present disclosure;

FIGS. 3A and 3B are a flow chart illustrating an exemplary method for use in implementing one embodiment of the present disclosure; and

FIG. 4 is a block diagram depicting one embodiment of the present disclosure for implementation within a NAND flash module.

### DETAILED DESCRIPTION

The present disclosure is directed to the reliable storage of data in read and write memory, and, in particular, to the reliable storage of data in non-volatile memory, such as, for example, NAND flash. Generally, and in particular regard to NAND flash memory, two separate banks of NAND flash are maintained by a controller. One bank contains economical MLC NAND flash, while a second bank contains high endurance SLC NAND flash. The controller conducts a data integrity test after every write. If a particular address range fails a data integrity test, the address range is remapped from MLC NAND flash to SLC NAND flash. As the SLC NAND flash is used to boost the lifetime (endurance) of the storage system, it can be considerably lesser in amount than the MLC NAND flash. For example, a system may set SLC NAND flash equal to 12.5% or 25% of MLC NAND flash (total non-volatile memory storage space=MLC+SLC).

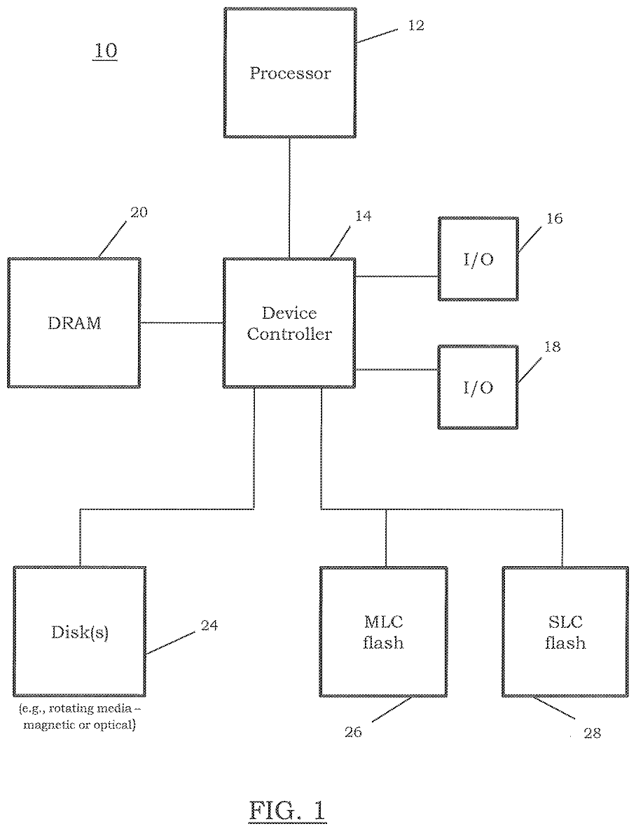

Turning to the Figures and to FIG. 1 in particular, a computer system 10 depicting one embodiment of the present disclosure is shown. A processor 12 is coupled to a device controller 14, such as a chipset, using a data link well known in the art, such as a parallel bus or packet-based link. The device controller 14 provides interface functions to the processor 12. In some computer systems, the device controller 14 may be an integral part of the (host) processor 12. The device controller 14 provides a number of input/output ports 16 and 18, such as, for example, serial ports (e.g., USB ports and Firewire ports) and network ports (e.g., Ethernet ports and 802.11 “Wi-Fi” ports). The device controller 14 may also control a bank of, for example, DRAM 20. In addition, the device controller 14 controls access to one or more disks 24, such as, for example, a rotating magnetic disk, or an optical disk, as well as two or more types of NAND flash memory. One type of NAND flash memory is a MLC NAND flash memory module 26. Another type of NAND flash memory is a SLC NAND flash memory module 28.

The device controller 14 maintains a translation table/address map which may include address translations for all devices in the computer system. Nonetheless, the discussion in the present disclosure will be limited only to NAND flash memory modules. In particular, the device controller 14 maintains a translation table that maps logical computer system addresses to physical addresses in each one of the MLC- and SLC-NAND flash memory modules 26 and 28, respectively. As MLC flash memory is less expensive than SLC flash memory, on a cost per bit basis, the translation table will initially map all logical NAND flash addresses to the MLC NAND flash memory module 26. The address ranges within the translation table will assume some minimum quantum, such as, for example, one block, although a smaller size, such as one page could be used, if the NAND flash has the capability of erasing the smaller size quantum.

A “read-modify-write” scheme is used to write data to the NAND flash. Data to be written to NAND flash is maintained in DRAM 20. After each write to an address within a particular address range, the device controller 14 will—as time permits—perform a read on the address range to ensure the integrity of the written data. If a data integrity test fails, the address range is remapped from the MLC NAND flash memory module 26 to the next available address range in the SLC NAND flash memory module 28.

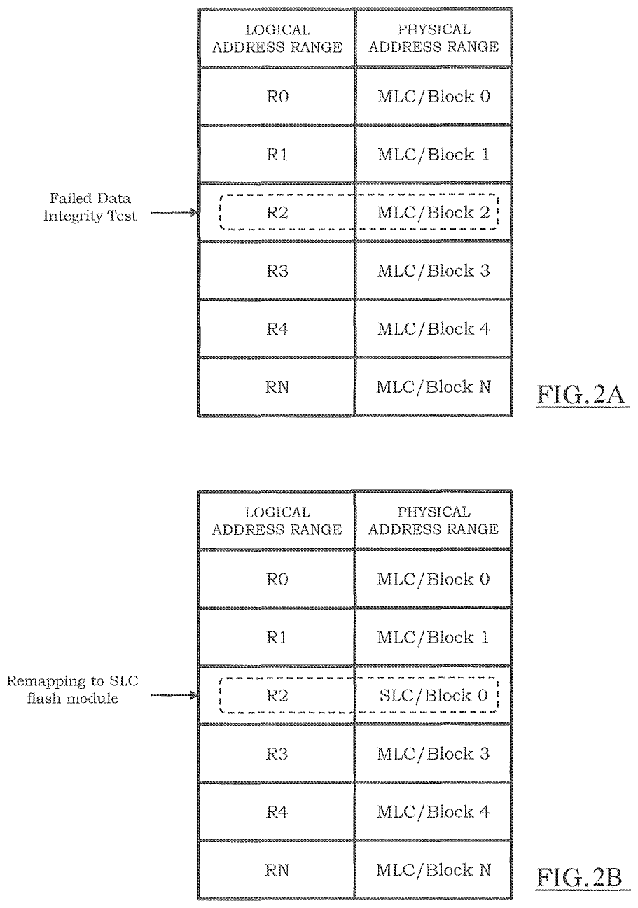

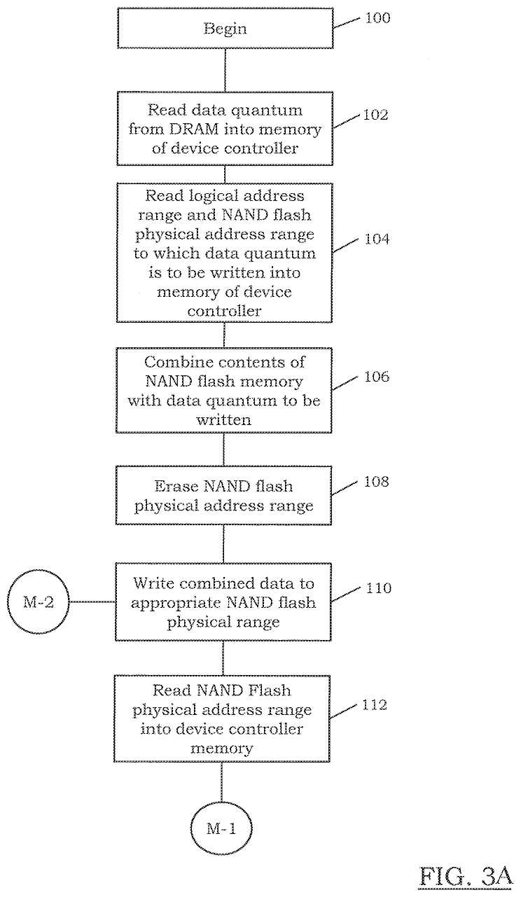

FIGS. 2A and 2B illustrate one embodiment of a translation table/address map of the present disclosure. In FIG. 2A, a list of logical address ranges (R0-RN) is translated to physical address ranges. As illustrated, all of the logical address ranges are translated to blocks on the MLC NAND flash memory module 26. However, through the application of a data integrity verification check (explained in more detail below) it is determined that, for example, address range R2 corresponds to failed quanta of data stored in block 2 of the MLC NAND flash memory module 26. FIG. 2B shows the quanta of data which failed the data integrity verification check (see FIG. 2A) remapped to the next available range of physical addresses within the SLC NAND flash memory module 28, in this example, SLC/block 0.

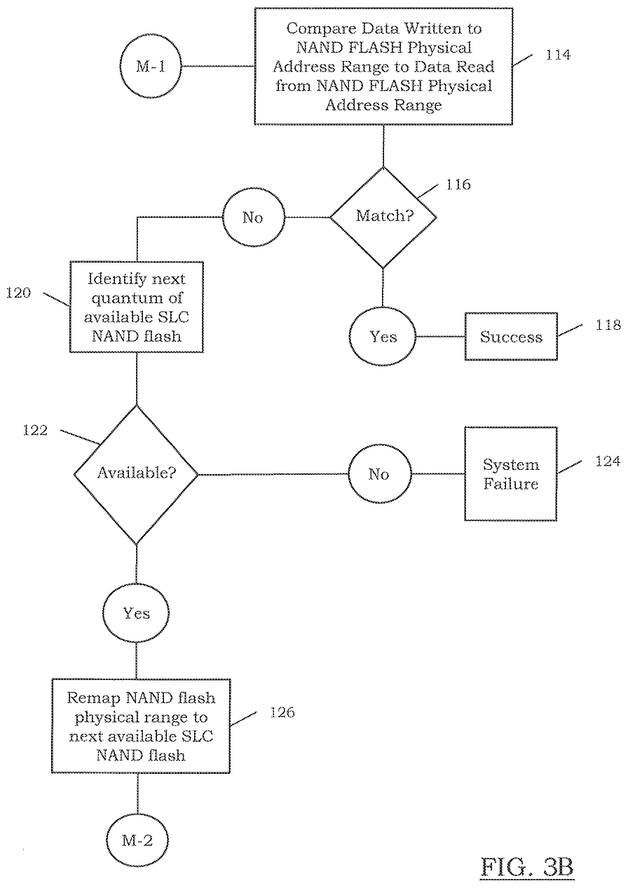

FIGS. 3A and 3B are a flow chart illustrating a method for utilizing a NAND flash memory system incorporating one embodiment of the present disclosure. The method begins in a step 100, when a command to write a quantum of data stored in DRAM to a particular location in NAND flash memory is received. In step 102, the quantum of data is read from DRAM into memory within the device controller (which acts as the memory controller). In step 104, both the logical address range and the NAND flash physical address range to which the quantum of data is to be written, is read into memory of the device controller. In step 106, the quantum of data to be written is combined with the contents of the NAND flash memory. In step 108, the NAND flash physical address range to be written is erased. In step 110, the combined data is written to the appropriate NAND flash physical address range. In step 112 the NAND flash physical address range that was written in step 110 is read into device controller memory.

The flowchart continues in FIG. 3B. In step 114 the NAND flash physical address range that was read into device controller memory is compared with the retained data representing the combination of the previous contents of the physical address range and the quantum of data to be written. In step 116, if the retained data matches the newly stored data in the NAND flash memory, the write was a success, and the method exits in step 118. However, if the retained data does not match the newly stored data in the NAND flash memory, the method executes step 120, which identifies the next quantum of available SLC NAND flash memory addresses. In step 122, a check is made to determine if additional SLC NAND flash memory is available, and, if not, the NAND flash memory system is marked as failed, prompting a system alert step 124. However, if additional SLC NAND flash memory is available, the failed NAND flash physical address range is remapped to the next available quantum of SLC NAND flash memory in step 126. Execution then returns to step 110, where the write is repeated.

Another application of one embodiment of the present disclosure, not depicted in any of the drawings, is to allocate “hot” blocks; i.e., those blocks that receive frequent writes, into the SLC NAND flash memory module 28, while allocating “cold” blocks; i.e., those blocks that only receive infrequent writes, into the MLC NAND flash memory module 26. This could be accomplished within the device controller 14 described above, which could simply maintain a count of those blocks that are accessed (written to) most frequently, and, on a periodic basis, such as, for example, every 1000 writes, or every 10,000 writes, transfer the contents of those blocks into the SLC NAND flash memory module 28.

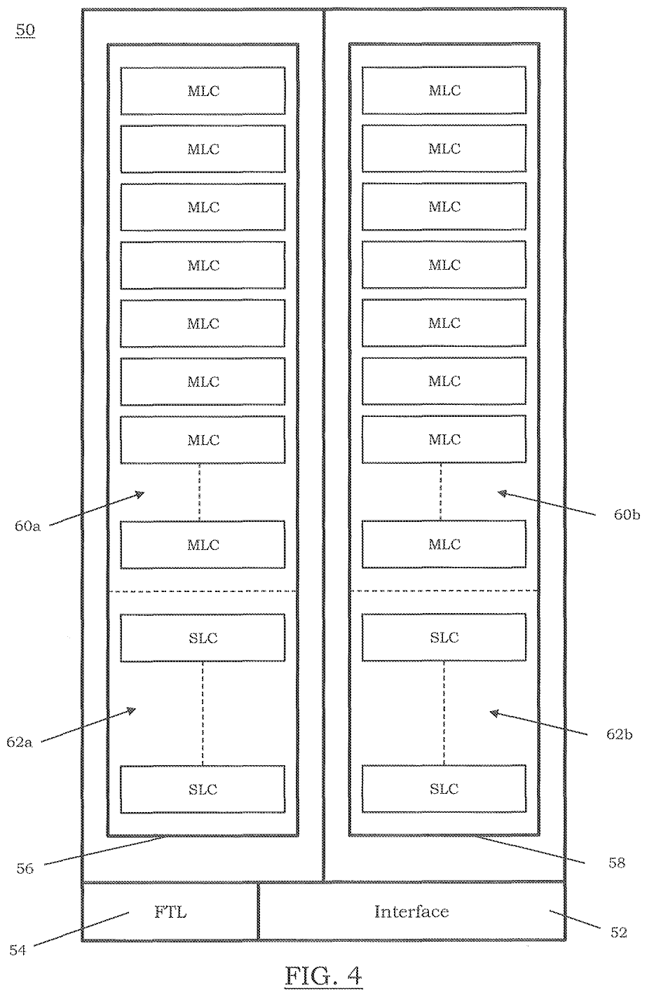

FIG. 4 depicts another embodiment of the present disclosure. The embodiment is entirely resident within a NAND flash module 50. In particular, a standard NAND flash interface 52 is managed by flash translation layer (FTL) logic 54. The flash translation layer (FTL) 54 manages two NAND flash memory banks 56 and 58, whereby memory bank 56 comprises a plurality of MLC NAND flash memory modules 60a and a plurality of SLC NAND flash memory modules 62a. Memory bank 58 comprises a plurality of MLC NAND flash memory modules 60b and a plurality of SLC NAND flash memory modules 62b.

This embodiment of the present disclosure could function similarly to the system level embodiment discussed earlier with reference to FIGS. 1-3B, but the control functions, such as maintenance of the translation table/address map (FIGS. 2A and 2B), could be conducted within the flash translation layer (FTL) 54 instead of in a device controller 14.

Embodiments of the present disclosure relate to a system and method of increasing the reliability and lifetime of a NAND flash storage system, module, or chip through the use of a combination of multi-level cell (MLC) and single-level cell (SLC) NAND flash storage. The above description is presented to enable one of ordinary skill in the art to make and use the disclosure and is provided in the context of a patent application and its requirements. While this disclosure contains descriptions with reference to certain illustrative aspects, it will be understood that these descriptions shall not be construed in a limiting sense. Rather, various changes and modifications can be made to the illustrative embodiments without departing from the true spirit, central characteristics and scope of the disclosure, including those combinations of features that are individually disclosed or claimed herein. Furthermore, it will be appreciated that any such changes and modifications will be recognized by those skilled in the art as an equivalent to one or more elements of the following claims, and shall be covered by such claims to the fullest extent permitted by law.

What is claimed is:

1. A system for storing data comprising:
an MLC non-volatile memory space including at least one MLC non-volatile memory element;
an SLC non-volatile memory module space including at least one SLC non-volatile memory element; and
a controller coupled to the at least one MLC non-volatile memory element and the at least one SLC non-volatile memory element wherein the controller is adapted to:
a) maintain an address map of the MLC and SLC non-volatile memory spaces, the address map comprising a list of logical address ranges accessible by a computer system, the computer system having at least one processor, the list of logical address ranges having a minimum quanta of addresses, wherein each entry in the list of logical address ranges maps to a similar range of physical addresses within either the at least one SLC non-volatile memory element or within the at least one MLC non-volatile memory element;
b) determine if a range of addresses listed by an entry and mapped to a similar range of physical addresses within the at least one MLC non-volatile memory element, fails a data integrity test performed at the controller during a read operation, reading stored data from the MLC non-volatile memory space containing at least one MLC non-volatile memory element, and, in an event of such a failure, the controller remaps the entry to a next available equivalent range of physical addresses within the at least one SLC non-volatile memory element.

2. The system of claim 1, wherein the minimum quanta of addresses is equal to one block.

3. The system of claim 1, wherein the minimum quanta of addresses is equal to one page.

4. The system of claim 1, wherein the at least one MLC non-volatile memory element is NAND flash memory.

5. The system of claim 1, wherein the at least one SLC non-volatile memory element is NAND flash memory.

6. The system of claim 1, wherein the at least one MLC non-volatile memory element is resistive random-access memory (RRAM).

7. The system of claim 1, wherein the at least one SLC non-volatile memory element is resistive random-access memory (RRAM).

8. The system of claim 1, wherein the at least one MLC non-volatile memory element is phase change memory (PCM).

9. The system of claim 1, wherein the at least one SLC non-volatile memory element is phase change memory (PCM).

10. The system of claim 1, wherein the at least one SLC non-volatile memory element is magnetic random-access memory (MA-GRAM).

11. The system of claim 1, wherein the controller causes a transfer of content on a periodic basis to enhance data integrity.

12. The system of claim 1, wherein the at least one MLC non-volatile memory element and the at least one SLC non-volatile memory element comprise a block with physical addresses.

13. The system of claim 1, wherein the at least one MLC non-volatile memory element and the at least one SLC non-volatile memory element comprise a page with physical addresses.

14. The system of claim 1, wherein the transfer of the stored data from the at least one MLC non-volatile memory element to the at least one SLC non-volatile memory element is temporary.

15. The system of claim 1, wherein the transfer of the stored data from the at least one MLC non-volatile memory element to the at least one SLC non-volatile memory element is temporary until an MLC non-volatile memory element is available.

16. The system of claim 1, wherein operations of the controller enhance a lifetime of the at least one MLC non-volatile memory element and the at least one SLC non-volatile memory element.

17. The system of claim 1, wherein the controller determines during a write operation if the range of addresses listed by the entry and mapped to the similar range of physical addresses within the at least one MLC non-volatile memory element, fails the data integrity test.

18. A method for storing data comprising:
providing an MLC non-volatile memory space including at least one MLC non-volatile memory element;
providing an SLC non-volatile memory space including at least one SLC non-volatile memory element; and
maintaining, using a controller coupled to the at least one MLC non-volatile memory element and the at least one SLC non-volatile memory element, an address map of the MLC and SLC non-volatile memory spaces, the address map comprising a list of logical address ranges accessible by a computer system, the computer system having at least one processor, the list of logical address ranges having a minimum quanta of addresses, wherein each entry in the list of logical address ranges maps to a similar range of physical addresses within either the at least one SLC non-volatile memory element or within the at least one MLC non-volatile memory element;
determining, using the controller, if a range of addresses listed by an entry and mapped to a similar range of physical addresses within the at least one MLC non-volatile memory element, fails a data integrity test performed at the controller during a data read operation from the at least one MLC non-volatile memory element in the MLC non-volatile memory space;
in an event of such a failure,
remapping, using the controller, the entry to a next available equivalent range of physical addresses within the at least one SLC non-volatile memory element; and
transferring the stored data from the at least one MLC non-volatile memory element to the at least one SLC non-volatile memory element using the controller.

19. A system for storing data comprising:
an MLC non-volatile memory space including at least one MLC non-volatile memory element;
an SLC non-volatile memory module space including at least one SLC non-volatile memory element; and
a controller coupled to the at least one MLC non-volatile memory element and the at least one SLC non-volatile memory element wherein the controller is adapted to:
a) maintain an address map of the MLC and SLC non-volatile memory spaces, the address map comprising a list of logical address ranges accessible by a computer system, the computer system having at least one processor, the list of logical address ranges having a minimum quanta of addresses, wherein each entry in the list of logical address ranges maps to a similar range of physical addresses within either the at least one SLC non-volatile memory element or within the at least one MLC non-volatile memory element;
b) determine if a range of addresses listed by an entry and mapped to a similar range of physical addresses within the at least one MLC non-volatile memory element, fails a data integrity test performed at the controller during a read-modify-write operation, reading stored data from the MLC non-volatile memory space containing at least one MLC non-volatile memory element, and, in an event of such a failure, the controller remaps the entry to a next available equivalent range of physical addresses within the at least one SLC non-volatile memory element.

20. A method for storing data comprising:
providing an MLC non-volatile memory space including at least one MLC non-volatile memory element;
providing an SLC non-volatile memory space including at least one SLC non-volatile memory element; and
maintaining, using a controller coupled to the at least one MLC non-volatile memory element and the at least one SLC non-volatile memory element, an address map of the MLC and SLC non-volatile memory spaces, the address map comprising a list of logical address ranges accessible by a computer system, the list of logical address ranges having a minimum quanta of addresses, wherein each entry in the list of logical address ranges maps to a similar range of physical addresses within either the at least one SLC non-volatile memory element or within the at least one MLC non-volatile memory element;
determining, using the controller, if a range of addresses listed by an entry and mapped to a similar range of physical addresses within the at least one MLC non-volatile memory element, fails a data integrity test performed at the controller during a read-modify-write operation from the at least one MLC non-volatile memory element in the MLC non-volatile memory space;
in an event of such a failure,
remapping, using the controller, the entry to a next available equivalent range of physical addresses within the at least one SLC non-volatile memory element; and
transferring the stored data from the at least one MLC non-volatile memory element to the at least one SLC non-volatile memory element using the controller.
